(19) United States
(12) Patent Application Publication
(10) Pub. No.: US 2008/0025821 A1
(43) Pub. Date: Jan. 31, 2008

(54) OCTAGON TRANSFER CHAMBER

(75) Inventors: John M. White, Hayward, CA (US); Takako Takehara, Hayward, CA (US)

Correspondence Address: PATTERSON & SHERIDAN, LLP, 3040 POST OAK BOULEVARD, SUITE 1500, HOUSTON, TX, 77056, US

(73) Assignee: APPLIED MATERIALS, INC.

(21) Appl. No.: 11/459,655

(22) Filed: Jul. 25, 2006

(51) Int. Cl. H01L 21/677

(52) U.S. Cl. 414/217

(57) ABSTRACT

A method and apparatus for processing substrates in a cluster tool is disclosed. The transfer chambers of the cluster tool have eight locations to which additional chambers (i.e., load lock, buffer, and processing chambers) may attach. The transfer chamber may be formed of three separate portions. The central portion may be a rectangular shaped portion. The two other portions may be trapezoidal shaped portions. The trapezoidal shaped portions each have three slots through which the substrate can move for processing. The central portion of the transfer chamber may have a removable lid that allows a technician to easily access the transfer chamber.

### BACKGROUND OF THE INVENTION

1. Field of the Invention

Embodiments of the present invention generally relate to a cluster tool for performing multiple processes on a substrate without breaking vacuum.

2. Description of the Related Art

When producing flat panel displays and solar panels, multiple processes are performed on a substrate in order to produce the finished product. These multiple processes are performed in a plurality of chambers. In some cases, the individual processes are performed in individual, isolated systems. Transferring the substrates from one processing system to another can be cumbersome and potentially introduce undesired contaminants. Performing multiple processes within a single system would be beneficial because it can save time and reduce contaminants.

### SUMMARY OF THE INVENTION

A method and apparatus for processing substrates in a cluster tool is disclosed. The transfer chambers of the cluster tool have eight locations to which additional chambers (i.e., load lock, buffer, and processing chambers) can attach. The transfer chamber may be formed of three separate portions. The central portion may be a rectangular shaped portion. The two other portions may be trapezoidal shaped portions. The trapezoidal shaped portions each have three slots through which the substrate can move for processing. The central portion of the transfer chamber may have a removable lid that allows a technician to easily access the transfer chamber.

In one embodiment, a cluster tool is described. The cluster tool may comprise an eight sided transfer chamber. Each side of the transfer chamber may have a slot formed therein through which a substrate may pass. As many as eight chambers may be directly coupled with the transfer chamber. The chambers may, for example, be processing chambers, load lock chambers, unload lock chambers, or buffer chambers.

In another embodiment, a cluster tool is described. The cluster tool comprises two transfer chambers. Each transfer chamber has an octagon shape with locations for eight chambers to attach. In another embodiment, the cluster tool comprises a hybrid transfer chamber system in which an octagon shaped transfer chamber is coupled to a hexagonal shaped transfer chamber through a buffer chamber. In yet another embodiment, a triple hybrid cluster tool is described. The cluster tool comprises a central octagon shaped transfer chamber coupled to two hexagonal transfer chambers through buffer chambers.

In another embodiment, a multi-piece octagon shaped transfer chamber is described. The multi-piece transfer chamber comprises a rectangularly shaped central section and two trapezoidal shaped sections. When the trapezoidal shaped sections are coupled to the rectangular shaped section, the transfer chamber is octagon shaped. By separating the transfer chamber into three sections, the octagon shaped transfer chamber may be easily transported from one location to another.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a plan view of a cluster tool according to one embodiment of the invention.

FIG. 2 is a plan view of a multi-cluster tool according to one embodiment of the invention.

FIG. 3 is a plan view of a multi-cluster tool according to another embodiment of the invention.

FIG. 4 is a plan view of a multi-cluster tool according to another embodiment of the invention.

FIG. 5 is an exploded isometric view of the transfer chamber according to one embodiment of the invention.

FIG. 6 is a top view of the transfer chamber according to one embodiment of the invention.

FIG. 7 is an isometric view of a trapezoidal section 700 of the transfer chamber according to one embodiment of the invention.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

The present invention comprises a cluster tool having a transfer chamber with eight locations to which additional chambers may attach. The additional chambers may include a load lock chamber, a buffer chamber, or process chambers.

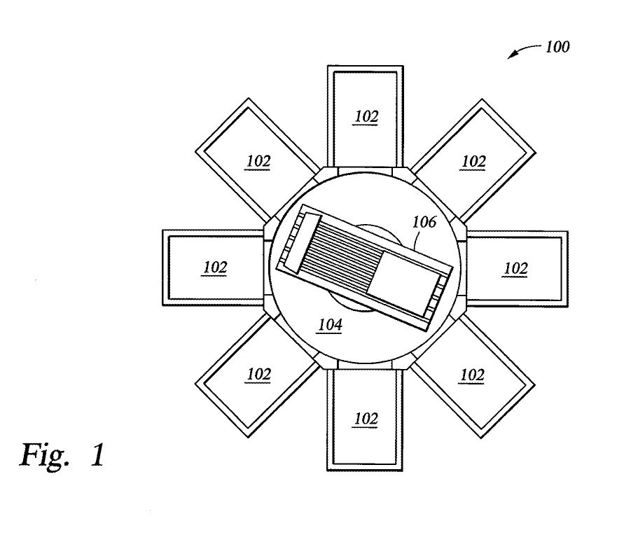

FIG. 1 is a plan view of a single-cluster tool 100 of one embodiment of the invention. The cluster tool 100 comprises a transfer chamber 104 with a robot 106 therein. The transfer chamber 104 has a body with eight sides. Each side may have one or more slits formed therein through which a substrate may pass into and out of the transfer chamber 104. Attached to each side of the transfer chamber 104 may be a processing chamber 102. The processing chambers 102 may be any processing chamber such as etching, chemical vapor deposition, physical vapor deposition, plasma enhanced chemical vapor deposition, etc. Additionally, any of the processing chambers 102 may be a load lock chamber or an unload lock chamber. The eight sided transfer chamber 104 provides the flexibility of performing multiple processes without breaking vacuum. In one embodiment, no load lock chamber is present around the transfer chamber 104, but rather, one of the processing chambers 102 functions to coupled with an adjacent chamber outside the cluster tool 100 and receives substrates and also processes the substrates.

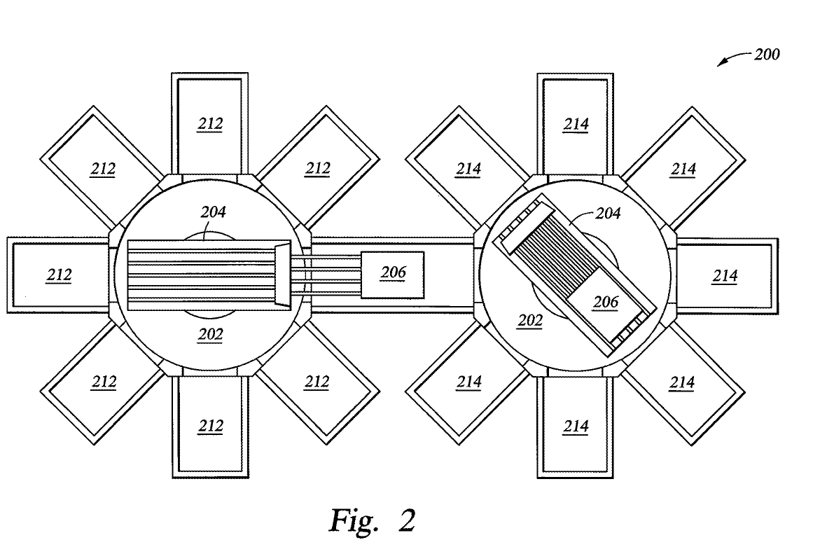

FIG. 2 is a plan view of a double cluster tool 200 of one embodiment of the present invention. The cluster tool 200 comprises two transfer chambers 202. Each transfer chamber 202 has eight processing locations. Within each transfer chamber 202, a transfer chamber robot 204 is present. The robot 204 rotates about its axis and may extend into the attached chambers to transport a substrate 206. A buffer chamber 208 joins the two transfer chambers 202 together. The substrate 206 may be transferred from one transfer chamber 202 through the buffer chamber 208 to the other transfer chamber 202. One robot 204 extends into the buffer chamber 208 to pass off the substrate 206. The other robot 204 extends into the buffer chamber 208 to receive the substrate 206. The robots 204 each retract into the transfer chamber 202 so that the substrate 206 may be delivered to the chambers that surround the transfer chamber 202.

The substrates 206 may be loaded into the cluster tool 200 through a load lock chamber 210. Additionally, following processing, the substrates 206 may be removed from the cluster tool 200 through the load lock chamber 210. Each transfer chamber 202 has a plurality of processing chambers 212, 214 attached thereto. At least six processing chambers 212, 214 are attached to each transfer chamber 202. When the load lock chamber 210 is used as both a load lock and an unload lock, one of the transfer chambers 202 may have seven processing chambers 214 and the other transfer chamber 202 may have six processing chambers 212. Of course, it is to be understood that any processing chamber may be replaced by an unload lock chamber should it be necessary for increased substrate throughput.

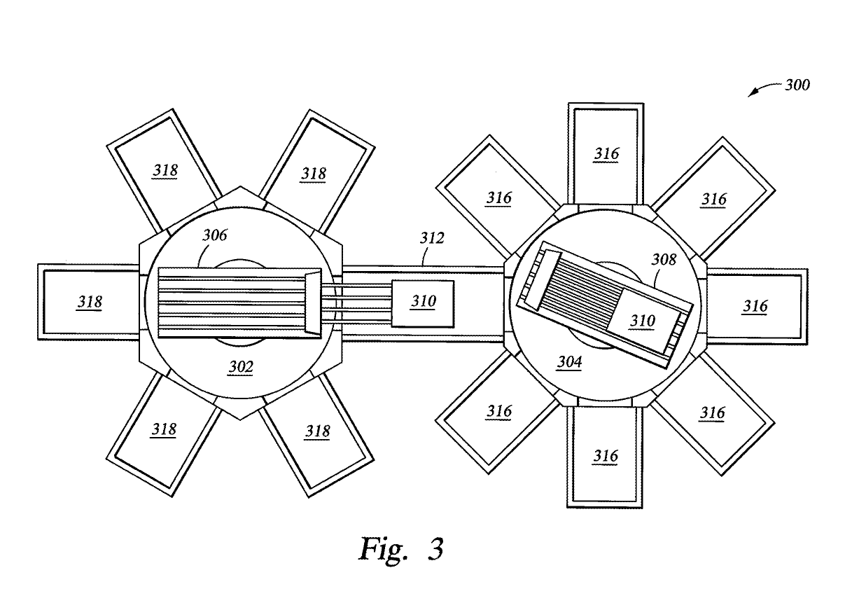

FIG. 3 is a plan view of a hybrid cluster tool 300 that has a hexagonal transfer chamber 302 and an octagon transfer chamber 304. The hexagonal transfer chamber 302 has six locations to which additional chambers can attach. The hexagonal transfer chamber 302 has a robot 306 therein that rotates about its axis and transports substrates 310 within the transfer chamber 302 and into processing chambers 318. The robot 306 extends into the processing chambers 318 to place substrates 310 into the processing chambers 318 and receive substrates 310 therefrom.

The octagon transfer chamber 304 has eight locations to which additional chambers can attach. The octagon transfer chamber 304 has a robot 308 therein that rotates about its axis and transports substrates 310 within the transfer chamber 304 and into processing chambers 314. The robot 308 extends into the processing chambers 314 to place substrates 310 into the processing chambers 314 and receive substrates 310 therefrom.

When transferring a substrate 310 from one transfer chamber 302 to the adjacent transfer chamber 304, the substrate 310 will pass through a buffer chamber 312 that connects the transfer chambers 302, 304. The robot 306 will extend into the buffer chamber 312 while holding the substrate 310. The robot 308 from the adjacent transfer chamber 304 will also extend into the buffer chamber 312 and receive the substrate 310. Both robots 306, 308 will then retract back into their respective transfer chambers 302, 304 so that the substrate 310 can be delivered to the chambers that surround the transfer chamber 304.

The hexagonal transfer chamber 302 may have five processing chambers 318 attached thereto. The octagon transfer chamber 304 may have six processing chambers 316 attached thereto and one load lock chamber 314. Substrates enter and exit the cluster tool 300 through the load lock chamber 314. It is to be understood that any processing chamber 314, 318 can be changed to an unload lock chamber should it be necessary to increase substrate throughput.

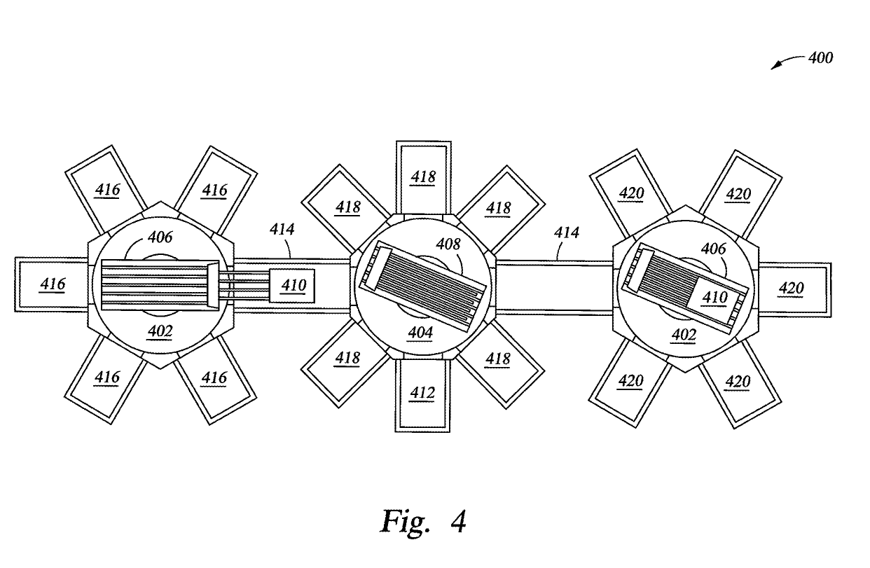

FIG. 4 is a plan view of another cluster tool 400 according to one embodiment of the present invention. The cluster tool 400 comprises two hexagonal transfer chambers 402 and one octagon transfer chamber 404. The hexagonal transfer chambers 402 each have six locations to which additional chambers may attach. The hexagonal transfer chambers 402 have a robot 406 therein that rotates about its axis and transports substrates 410 within the transfer chamber 402 and into processing chambers 416, 420. The robot 406 extends into the processing chambers 416, 420 to place substrates 410 into the processing chambers 416, 420 and receive substrates 410 therefrom.

The octagon transfer chamber 404 has eight locations to which additional chambers can attach. The octagon transfer chamber 404 has a robot 408 therein that rotates about its axis and transports substrates 410 within the transfer chamber 404 and into processing chambers 418. The robot 408 extends into the processing chambers 418 to place substrates 410 into the processing chambers 418 and receive substrates 410 therefrom.

When transferring a substrate 410 from one transfer chamber 402, 404 to an adjacent transfer chamber 402, 404, the substrate 410 will pass through a buffer chamber 414 that connects the transfer chambers 402, 404. The robot 406 will extend into the buffer chamber 414 holding the substrate 410. The robot 408 from the adjacent transfer chamber 404 will also extend into the buffer chamber 414 and receive the substrate 410. Both robots 406, 408 will then retract back into their respective transfer chambers 402, 404 so that the substrate 410 can be delivered to the chambers that surround the transfer chamber 404.

The hexagonal transfer chambers 402 may have five processing chambers 416, 420 attached thereto. The octagon transfer chamber 404 may have five processing chambers 418 attached thereto and one load lock chamber 412. Substrates enter and exit the cluster tool 400 through the load lock chamber 412. It is to be understood that any processing chamber 416, 418, 420 may be changed to an unload lock chamber should it be necessary to increase substrate throughput.

The processing chambers for the above described embodiments may be any chamber that is used for processing a substrate such as deposition chambers, etching chambers, and annealing chambers. In one embodiment, the processing chambers are all deposition chambers used to deposit the layers necessary for forming a PINPIN double junction. The processing chambers may comprise processing chambers for depositing n-doped silicon, p-doped silicon, amorphous silicon, or microcrystalline silicon.

In one embodiment, at least one processing chamber may be configured to deposit a p-doped silicon layer and at least one processing chamber may be configured to deposit an n-doped silicon layer. The remaining chambers may be configured to deposit an intrinsic silicon layer. The intrinsic silicon layer deposition chamber may deposit either an amorphous silicon or a microcrystalline layer. In PIN type structures, the “I” or intrinsic layer of the PIN junction takes a longer amount of time to deposit than the “P” (i.e., p-doped silicon) or “N” (i.e., n-doped silicon) layers. Therefore, having multiple processing chambers attached to a common transfer chamber may be beneficial because an eight sided transfer chamber may compensate for the additional time needed to form the “I” layers.

For example, a four sided cluster tool may comprise a load lock chamber, a “P” deposition chamber, an “I” deposition chamber, and an “N” deposition chamber. Because the “I” layer takes a longer time to deposit than the “P” or “N” layers, substrate throughput will not be efficient. Once a substrate has a “P” layer deposited thereon, it would be moved to the “I” deposition chamber. During the time that the “I” layer is deposited on the “P” layer, an additional substrate may be processed in the “P” chamber to deposit a “P” layer. However, once the “P” layer is deposited, the “I” chamber would not be available because the “I” chamber would still be depositing an “I” layer on the previous substrate. Thus, the “P” and “N” chambers would sit idle.

An eight sided transfer chamber may increase substrate throughput in PIN type applications. To compensate for the slower “I” deposition processes, additional “I” processing chambers may be added to the cluster. Thus, for an eight sided transfer chamber, as opposed to a four sided transfer chamber, the “P” deposition chambers may transfer a substrate to an additional “I” deposition chamber and then receive a new substrate to process. The eight sided transfer chamber may accommodate a sufficient number of processing chambers to allow a technician to optimize the number of processing chambers dedicated to each of the “P”, “I”, and “N” layers and increase substrate throughput by reducing processing chamber downtime.

It is to be understood that the phrase “PIN type structures” is a generic term used to describe all structures containing all three layers (ie., a “P” layer an “I” layer, and an “N” layer). Examples of PIN type structures include a single PIN structure, a PINPIN structure where the “I” layer is intrinsic microcrystalline silicon, a hybrid PINPIN structure where one “I” layer is intrinsic amorphous silicon and one “I” layer is intrinsic microcrystalline silicon, and a PINPIN structure where the “I” layer is intrinsic amorphous silicon.

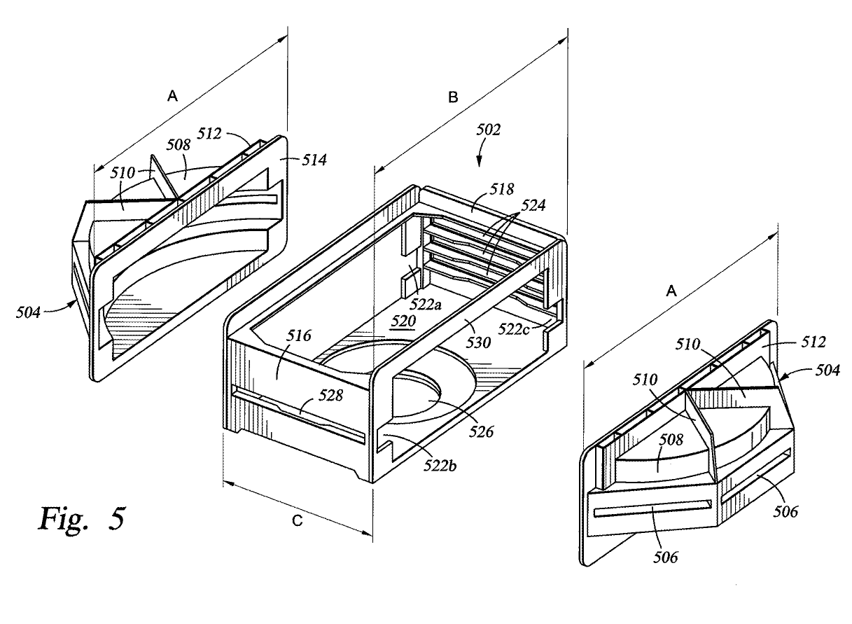

FIG. 5 shows an exploded isometric view of an octagon transfer chamber according to one embodiment of the present invention. The transfer chamber is divided into three sections. A center section 502 is rectangular shaped and the two end sections 504 are trapezoidal shaped. When processing large area substrates, the transfer chamber can be quite large. So large, in fact, that the transfer chamber cannot be easily transported. Therefore, the transfer chamber may be separated into three sections. One center section 502 and two trapezoidal sections 504. When the sections are all placed together, the transfer chamber will be an octagon shaped transfer chamber.

The center section 502 comprises opposing walls 516, 518. One wall 516 will have an opening 528 through which substrates may be transported for processing. The other wall 518 may comprise three openings 524 through which substrates can be transported. It should be understood that any number of openings may be present (ie., 1, 2, 4, 5, etc.). The center section 502 includes a bottom 520 that has an opening 526 for the transfer chamber robot (not shown). A bonding interface 530 is also present on a side of the center section 502. The interface surface 530 is for interfacing with the trapezoidal sections. Notches 522a-c are present within the center section 502 to allows more space for substrates to pass through unimpeded to the processing chambers. The interface surface 530 has a width labeled with arrows B.

The trapezoidal sections 504 include openings 506 through which substrates can pass into processing chambers. The top of the trapezoidal sections have a cylindrical wall 508 and fin structures 510. The fin structures are anchored to a fin support wall 512. The fin structures 510 support the roof of the trapezoidal sections 504 to ensure that the roof will not bow in the middle or collapse into the transfer chamber. The trapezoidal sections 504 have an interface surface 514 with a length shown by arrows A. The length of the interface surface 514 of the trapezoidal sections 504 is equal to the length of the interface surface 530 of the center section 502. The interface surfaces 514, 530 can be sealed together using an O-ring.

The sides of the sections 502, 504 that have the openings 516, 524, 506 have a width shown by arrows C, D. The width of each side having an opening 506, 516, 524 are of equal length. Additionally, the openings 506, 516, 524 are of equal width and height. By having the sidewalls of equal width, it is easy to interchange chambers (i.e., buffer chambers, processing chambers, and load lock chambers) that attach to the transfer chamber.

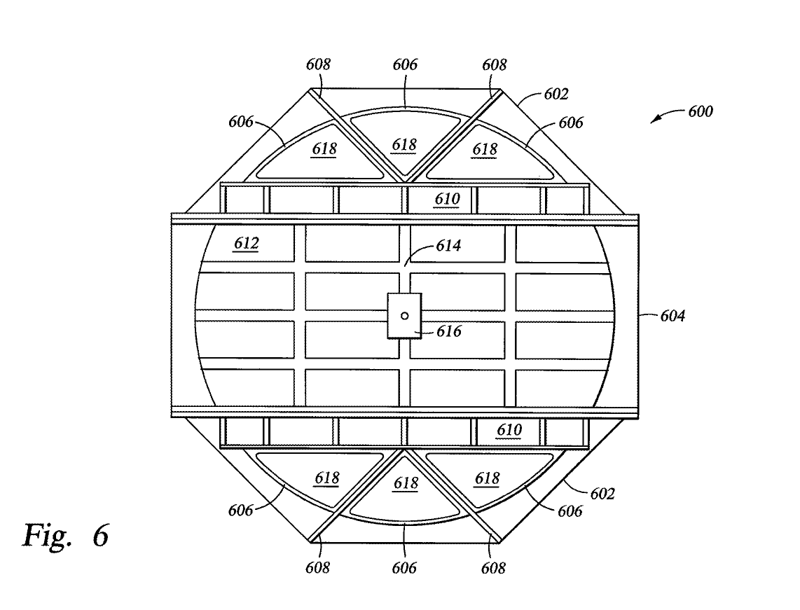

FIG. 6 shows a top view of a transfer chamber 600 that has been assembled from three sections 602, 604. The center section 604 is rectangular shaped and the end sections 602 are trapezoidal shaped. Once the sections 602, 604 are sealed together, the octagon shaped transfer chamber 600 is formed. The trapezoidal sections 602 have cylindrical roofs 606 and fin structures 608 that support the cylindrical roof 606 to ensure that it does not bow or collapse into the transfer chamber 600. The fin structures are anchored to a fin support wall 610. Removable lids 618 may be coupled with the section 602. The lids 618 may be positioned between the fin structures 608.

The center section 604 has a roof 612 that is supported by a lid support 614 that spans across the entire roof in a mesh pattern. The lid support 614 prevents the roof 612 from collapsing into the transfer chamber 600. Additionally, the lid support 614 makes the lid 612 more rigid so that it can easily be removed without scraping against any walls of the transfer chamber 600. The lid 612 may be removed by lifting the lid handle 616. Once the lid 612 is removed, the inside of the assembled transfer chamber 600 may be easily serviced by a technician.

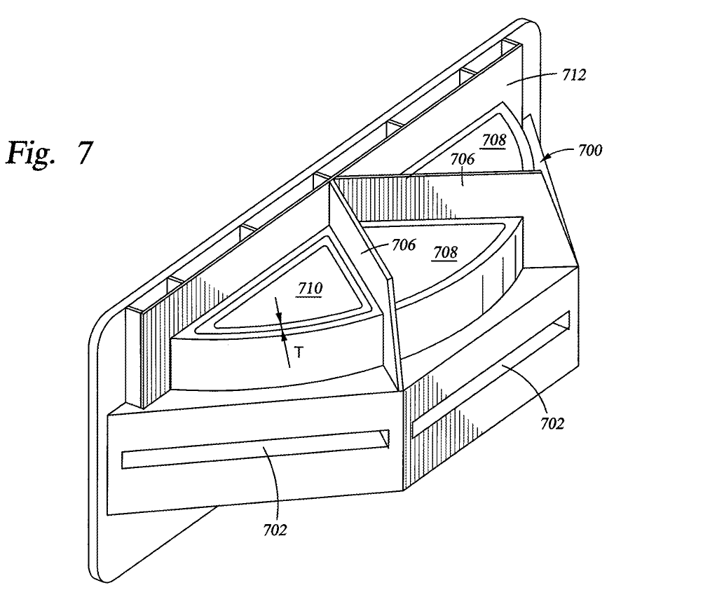

FIG. 7 shows an isometric view of a trapezoidal section 700 of the transfer chamber. As can be seen from FIG. 7, one or mores slots 702 may be positioned along the sides of the trapezoidal section 700. The one or more slots 702 are positioned to permit passage of a substrate therethrough. The roof of the trapezoidal section 700 may be supported by fin structures 706 that may be coupled with a fin support wall 712. The roof of the triangular portions between the fin structures 706 may each have an opening 710 therethrough. The openings 710 may be covered with a lid 708. The lids 708 may be adapted to seal the openings 710 in a top portion of the trapezoidal section 700 by employing a sealing member. In one embodiment, the sealing member may be an O-ring. FIG. 7 shows only one opening 710 and two lids 708, but it is to be understood that under each lid 708, an opening may be present. It is also to be understood that a lid 708 may be positioned over the opening 710.

To aid in the sealing of the openings 710, a flat surface may be machined into the top portion of the trapezoidal section 700 around the openings 710. For example, for a 20 mm thick chamber top portion, an approximately 2 mm deep flat surface may be provided in the top portion of the trapezoidal sections 700 for an O-ring to create a sealing flange around the periphery of the openings 710. The flange thickness T may be approximately 1.2 inches with an approximately 0.015 inch O-ring groove clearance for lid rubbing. Any conventional fastener known in the art may be used to fasten the lid 708 to the trapezoidal section 700.

In some embodiments, the openings 710 may be as large as possible without compromising the structural integrity of the chamber particularly when the chamber is under vacuum pressure. More than two openings 710 may be provided. The openings 710 may be located generally in the center of each triangular portion of the trapezoidal section 700 between the fin structures 706. Other locations are also contemplated. The openings 710 may be generally shaped to match the general shape of the part of the top portion of the trapezoidal section 700, but other shapes are also possible. The openings 710 may be suitable to provide access and/or a view into the chamber without having to disassemble the chamber. The openings 710 and corresponding lids 708 may have any shape that it practicable. The openings 710 may be useful for cleaning the chamber, retrieving an object that may have inadvertently deposited in the chamber, and/or for monitoring or viewing activity within the chamber. The lids 708 may be made from aluminum or any practicable material. In some embodiments, the lids 708 may include a sealed window or may be made from an optically transmissive material. In one embodiment, the lid 708 may be curved or domed shaped to improve the structural integrity of the lids 708.

Each section of the transfer chamber may be made of aluminum, stainless steel, or any conventionally used inert material suitable for use as a transfer chamber.

When a substrate is transferred from one transfer chamber to another transfer chamber, the substrate is not undergoing any processing. It is beneficial to lessen the time necessary to transfer a substrate when it is within a cluster tool. By increasing the number of processing chambers that are attached to the transfer chamber, substrate throughput can be increased.

While the foregoing is directed to embodiments of the present invention, other and further embodiments of the invention may be devised without departing from the basic scope thereof, and the scope thereof is determined by the claims that follow.

We claim:

1. A transfer chamber, comprising:
a body having eight faces, the body having a removable lid;
each face having one or more slit openings formed therein;
at least one load lock chamber coupled with the body; and
at least one processing chamber coupled with the body.

2. The transfer chamber of claim 1, further comprising:
a central piece having a generally rectangular shape, the central piece comprising a removable lid, wherein the lid comprises a plurality of support structures, wherein the central piece has a first planar side and a second planar side, wherein the first planar side and the second planar side are parallel and of equal length;
a first side piece coupled to the central piece, wherein one side of the first side piece has a length equal to the length of the first planar side of the central piece; and
a second side piece coupled to the central piece, wherein one side of the second side piece has a length equal to the length of the second planar side of the central piece; wherein the chamber is formed by coupling the first side piece and the second side to the central piece, and wherein the plurality of support structures are located outside the chamber.

3. The cluster tool of claim 2, wherein the first side piece and the second side piece are each trapezoidal shaped.

4. The cluster tool of claim 2, wherein the first side piece and the second side piece each comprise a plurality of support fins that are present on a roof of the first side piece and the second side piece.

5. The cluster tool of claim 2, wherein the removable lid comprises a mesh lattice of support beams and a lid handle.

6. The cluster tool of claim 2, wherein each side piece comprises three sides that each comprise an opening through which a substrate can pass.

7. The cluster tool of claim 2, wherein the central piece comprises two sides that each comprise at least one opening through which a substrate can pass.

8. A cluster tool, comprising:
a plurality of transfer chambers, wherein at least one transfer chamber has eight locations to which additional chambers can attach, and wherein each transfer chamber is coupled to another transfer chamber through a buffer chamber;
a plurality of processing chambers coupled to the transfer chambers, wherein each transfer chamber has at least five process chambers coupled to it; and
only one load lock chamber, wherein the load lock chamber is coupled to a transfer chamber.

9. The cluster tool of claim 8, further comprising two transfer chambers, wherein one transfer chamber comprises seven processing chambers and the other transfer chamber comprises six processing chambers.

10. The cluster tool of claim 8, further comprising two transfer chambers, wherein one transfer chamber comprises a hexagonal shape and the other transfer chamber comprises an octagon shape.

11. The cluster tool of claim 8, the at least one transfer chamber comprises:
a central piece having a generally rectangular shape, the central piece comprising a removable lid, wherein the lid comprises a plurality of support structures, wherein the central piece has a first planar side and a second planar side, wherein the first planar side and the second planar side are parallel and of equal length;
a first side piece coupled to the central piece, wherein one side of the first side piece has a length equal to the length of the first planar side of the central piece; and
a second side piece coupled to the central piece, wherein one side of the second side piece has a length equal to the length of the second planar side of the central piece;
wherein the transfer chamber is formed by coupling the first side piece and the second side to the central piece, and wherein the plurality of support structures are located outside the transfer chamber.

12. The cluster tool of claim 11, wherein the first side piece and the second side piece are each trapezoidal shaped.

13. A cluster tool, comprising:
at least one transfer chamber having eight locations to which additional chambers can attach;
at least one transfer chamber having six locations to which additional chambers can attach, wherein each transfer chamber is coupled to another transfer chamber through a buffer chamber;
at least five process chambers coupled to each transfer chamber; and
one load lock chamber coupled to the at least one transfer chamber having eight locations, wherein no load lock chambers are coupled to any of the at least one transfer chamber having six locations.

14. The cluster tool of claim 13, wherein the at least one transfer chamber having eight locations further comprises:
a central piece having a generally rectangular shape, the central piece comprising a removable lid, wherein the lid comprises a plurality of support structures, wherein the central piece has a first planar side and a second planar side, wherein the first planar side and the second planar side are parallel and of equal length;
a first side piece coupled to the central piece, wherein one side of the first side piece has a length equal to the length of the first planar side of the central piece; and
a second side piece coupled to the central piece, wherein one side of the second side piece has a length equal to the length of the second planar side of the central piece;
wherein the transfer chamber is formed by coupling the first side piece and the second side to the central piece, and wherein the plurality of support structures are located outside the transfer chamber.

15. The cluster tool of claim 14, wherein the first side piece and the second side piece are each trapezoidal shaped.

16. The cluster tool of claim 14, wherein the first side piece and the second side piece each comprise a plurality of support fins that are present on a roof of the first side piece and the second side piece.

17. The cluster tool of claim 14, wherein the removable lid comprises a mesh lattice of support beams and a lid handle.

18. A cluster tool, comprising:
one transfer chamber having eight locations to which additional chambers can attach;
two transfer chambers having six locations to which additional chambers can attach, wherein each transfer chamber having six locations is coupled to the transfer chamber having eight locations through a buffer chamber;
one load lock chamber coupled to the transfer chamber having eight locations; and
five process chambers coupled to each transfer chamber.

19. The cluster tool of claim 18, wherein the at least one transfer chamber having eight locations further comprises:
a central piece having a generally rectangular shape, the central piece comprising a removable lid, wherein the lid comprises a plurality of support structures, wherein the central piece has a first planar side and a second planar side, wherein the first planar side and the second planar side are parallel and of equal length;
a first side piece coupled to the central piece, wherein one side of the first side piece has a length equal to the length of the first planar side of the central piece; and
a second side piece coupled to the central piece, wherein one side of the second side piece has a length equal to the length of the second planar side of the central piece;
wherein the transfer chamber is formed by coupling the first side piece and the second side to the central piece, and wherein the plurality of support structures are located outside the transfer chamber.

20. The cluster tool of claim 19, wherein the first side piece and the second side piece are each trapezoidal shaped.

21. The cluster tool of claim 19, wherein the first side piece and the second side piece each comprise a plurality of support fins that are present on a roof of the first side piece and the second side piece.

22. The cluster tool of claim 19, wherein the removable lid comprises a mesh lattice of support beams and a lid handle.

23. A method of processing a substrate, comprising:
placing a substrate in a transfer chamber, wherein the transfer chamber has eight locations to which additional chambers are attached, the transfer chamber comprising:
a central piece having a generally rectangular shape, the central piece comprising a removable lid, wherein the lid comprises a plurality of support structures, wherein the central piece has a first planar side and a second planar side, wherein the first planar side and the second planar side are parallel and of equal length;
a first side piece coupled to the central piece, wherein one side of the first side piece has a length equal to the length of the first planar side of the central piece; and
a second side piece coupled to the central piece, wherein one side of the second side piece has a length equal to the length of the second planar side of the central piece;
wherein the chamber is formed by coupling the first side piece and the second side to the central piece, and wherein the plurality of support structures are located outside the chamber; and
transferring the substrate into a plurality of processing chambers.

24. The method of claim 23, wherein the first side piece and the second side piece are each trapezoidal shaped.

25. The method of claim 23, wherein the first side piece and the second side piece each comprise a plurality of support fins that are present on a roof of the first side piece and the second side piece.

26. The method of claim 23, wherein the removable lid comprises a mesh lattice of support beams and a lid handle.
